(19) United States
(12) Patent Application Publication
(10) Pub. No.: US 2022/0223752 A1
(43) Pub. Date: Jul. 14, 2022

(54) METHOD FOR MANUFACTURING SOLAR CELL PANEL COMPRISING PREPREG BY MEANS OF AUTOCLAVE

(71) Applicant: Edison Motors Co., Ltd, Gyeongsangnam-do (KR)

(72) Inventors: Sung Min HONG, Busan (KR); Jong Cheol JEONG, Gyeongsangnam-do (KR); Bo Seong KIM, Gyeongsangnam-do (KR); Soo Hwan KANG, Gyeongsangnam-do (KR)

(73) Assignee: Edison Motors Co., Ltd, Gyeongsangnam-do (KR)

(21) Appl. No.: 17/613,117

(22) PCT Filed: Aug. 18, 2020
(86) PCT No.: PCT/KR2020/010965

§ 371 Date: Nov. 22, 2021

(30) Foreign Application Priority Data
Nov. 29, 2019 (KR) 10-2019-0156484

(51) Int. Cl. H01L 31/048

(52) U.S. Cl. CPC H01L 31/048

(57) ABSTRACT

The present invention relates to a method for manufacturing a solar cell panel by means of an autoclave, the method comprising the steps of: (a) positioning at least one solar cell module on a mold having a release material layer; (b) laminating a prepreg on the mold by a predetermined thickness so as to cover the solar cell module; (c) covering a laminated structure of the solar cell module and prepreg with a bagging film and encapsulating the inner space of the bagging film from the outside; and (d) making the inner space of the bagging film into a vacuum state, and then inputting the mold into a chamber of an autoclave and pressing and hardening the prepreg by applying heat and pressure, wherein, in step (b), a mounting space for forming a solar cell panel is provided on the mold, and the prepreg is laminated while the solar cell module is insertedly positioned in a fixing groove formed on a mounting surface of the mounting space.

### TECHNICAL FIELD

The present disclosure relates to a method of manufacturing a solar cell panel including a prepreg using an autoclave, and more particularly, to a highly rigid and lightweight solar cell panel installable on the top of a vehicle.

### BACKGROUND ART

Recently, various studies have been conducted on alternative energy sources that may replace existing fossil fuels to solve energy problems. In particular, a wide range of studies have been conducted to use natural energy such as wind power and solar power, and a solar cell using solar light is an infinite and eco-friendly resource and thus much attention has been paid thereto as an alternative energy source.

The solar cell is a device that converts light energy of the sun into electrical energy and is a key component of a solar power generation system, and for solar power generation, multiple solar cells are connected in series to manufacture a panel type module and such modules are connected to each other in series and parallel.

To apply such a solar cell to the field of automobiles, studies have been actively conducted to mount solar cells, and a solar cell panel is mounted on a top surface of the body in the case of some hybrid electric vehicles or electric vehicles (EVs).

However, in order to apply a solar cell module to the top of a vehicle, the solar cell panel is manufactured in advance and fixed on the vehicle using a mechanical fixing structure, but in this case, an additional structure should be installed to fixedly install the solar cell module on the vehicle and the weight of the vehicle increases.

Therefore, there is a need to develop a method of manufacturing a solar cell panel for solving the problem with installing such a solar cell module and securing an area for installation of the solar cell module to increase efficiency.

### DISCLOSURE

### Technical Problem

An aspect of the present invention provides a method of manufacturing a lightweight solar cell panel applicable to the top of a vehicle without installing an additional fixing structure and having high rigidity to withstand external impacts.

### Technical Solution

According to an aspect of the present invention, a method of manufacturing a solar cell panel using an autoclave includes (a) disposing at least one solar cell module on a mold having a release material layer, (b) stacking a prepreg on the mold to a certain thickness so as to cover the solar cell module, (c) covering a stacked structure of the solar cell module and the prepreg with a bagging film and sealing an inner space of the bagging film from the outside, and (d) making the inner space of the bagging film into a vacuum state, placing the mold into a chamber of an autoclave, and applying pressure and heat to compress and harden the prepreg, wherein, in (b), the mold is provided with a mounting space for forming a solar cell panel, and the prepreg is stacked in a state in which the solar cell module is inserted into a fixing groove formed in a mounting surface of the mounting space.

In an embodiment of the present invention, the mounting surface of the mold may have a certain curvature and may be upwardly convex.

In an embodiment of the present invention, the mounting surface of the mold may have a certain curvature and may be concave.

In an embodiment of the present invention, in operation (b), the fixing groove may be recessed to a depth sufficient to outwardly expose a portion of the solar cello module and the prepreg may be stacked to cover the exposed portion.

In an embodiment of the present invention, the prepreg may include a first region corresponding to the solar cell module, and a second region formed in a peripheral region of the first region along an inner side of the mounting space.

In an embodiment of the present invention, the prepreg may be stacked to be thicker in the second region than in the first region.

### Advantageous Effects

According to an embodiment of the present invention, a highly rigid and lightweight solar cell panel can be manufactured using an autoclave technique after forming a curved structure by stacking a prepreg in multiple layers in a state in which a fixing groove is formed in a mounting space of a mold to increase the accuracy of arrangement of a solar cell module.

The solar cell panel manufactured by the above method can be installed on the top of a vehicle without an additional fixing structure and used as a component of the body of the vehicle, which has rigidity sufficient to withstand external impacts.

### DESCRIPTION OF DRAWINGS

FIG. 1 is a flowchart of a manufacturing method of a solar cell panel according to a first embodiment of the present invention.

FIG. 2 is a cross-sectional view illustrating a process of the manufacturing method of a solar cell panel according to the first embodiment of the present invention.

FIG. 3 is a schematic diagram of a first mold for manufacturing a solar cell panel according to the first embodiment of the present invention.

FIG. 4 is a cross-sectional view illustrating a process of a manufacturing method of a solar cell panel according to a second embodiment of the present invention.

FIG. 5 is a schematic diagram of a second mold for manufacturing a solar cell panel according to the second embodiment of the present invention.

FIG. 6 is a schematic cross-sectional view illustrating a state in which a first solar cell panel according to the first embodiment and a second solar cell panel according to the second embodiment of the present invention are connected to each other on the top of a vehicle.

### MODES OF THE INVENTION

Hereinafter, configurations and operations of embodiments of the present invention will be described in detail with reference to the accompanying drawings.

However, it should be understood that the present invention is not limited to particular embodiments and include all modifications, equivalents, and alternatives falling within the idea and scope of the present invention.

It should be understood that the terms “comprise” and/or “comprising”, when used herein, specify the presence of stated features, steps, operations, elements, components, or a combination thereof, but do not preclude the presence or addition of one or more other features, steps, operations, elements, components, or a combination thereof. That is, it will be understood that when an element is referred to as “including” another element, the element may further include other elements unless specifically mentioned otherwise.

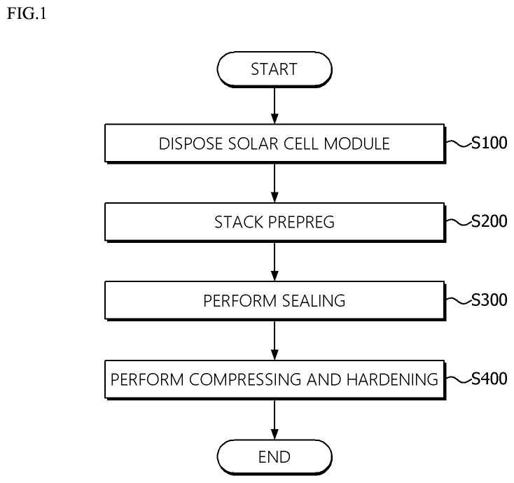

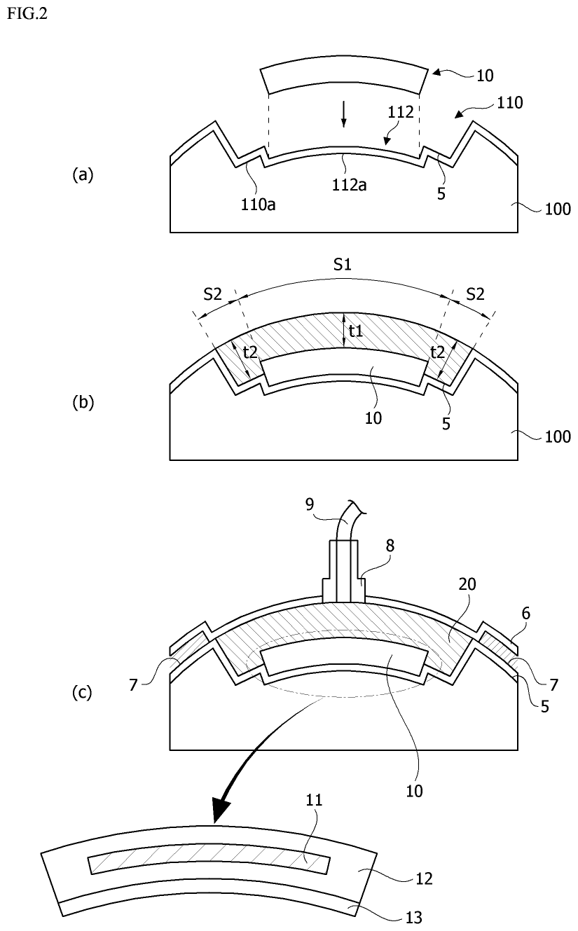

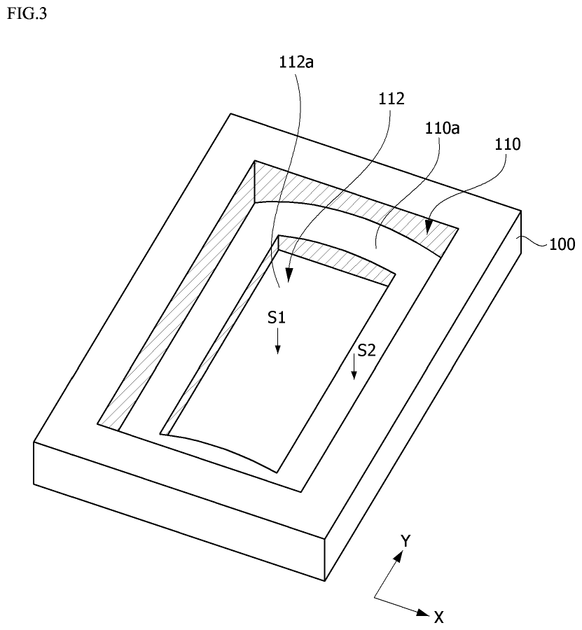

FIG. 1 is a flowchart of a manufacturing method of a solar cell panel according to a first embodiment of the present invention. FIG. 2 is a cross-sectional view illustrating a process of the manufacturing method of a solar cell panel according to the first embodiment of the present invention. FIG. 3 is a schematic diagram of a first mold for manufacturing a solar cell panel according to the first embodiment of the present invention.

Referring to FIG. 1, a manufacturing method of a solar cell panel according to an embodiment of the present invention may include disposing a solar cell module (S100), stacking a prepreg (S200), performing sealing (S300), and performing compressing and hardening (S400).

Referring to FIGS. 2 and 3, a first mold 100 may be formed of a metal to form a solar cell panel including a prepreg having a certain level of curvature and a curved shape. Here, the metal may be aluminum or steel.

In the disposing of the solar cell module (S100) according to an embodiment of the present invention, the solar cell module 10 may be disposed on the first mold 100 provided to manufacture a solar cell panel.

The solar cell module 10 according to an embodiment of the present invention may include a solar cell 11, an encapsulation layer (EVA sheet) 12 covering an outer side of the solar cell 11 while exposing an electrode terminal (not shown) of the solar cell 11, and a light transmission layer 13 provided on a side of the encapsulation layer 12.

According to an embodiment of the present invention, the first mold 100 may include a first mounting space 110 for forming a solar cell panel having a curved surface.

The first mounting space 110 may be formed in a quadrilateral shape when viewed from a plane, and a first mounting surface 110a may have an upwardly convex shape having a certain curvature on an xy plane.

A first fixing groove 112 may be formed in the first mounting surface 110a to increase the accuracy of arrangement of the solar cell module 10.

According to an embodiment of the present invention, the first fixing groove 112 may be recessed to a certain depth while forming a step with the first mounting surface 110a of the first mounting space 110.

The first fixing groove 112 may be formed with a first fixing bottom surface 112a that is upwardly convex on the XY plane, and the first fixing bottom surface 112a may have a convex shape having the same curvature as the first mounting surface 110a of the first mounting space 110.

Although in the drawings of the present specification, the first fixing bottom surface 112a and the first mounting surface 110a have the same curvature, the first fixing bottom surface 112a and the first mounting surface 110a may be formed to have different curvatures when a shape of a solar cell module used in the manufacture of the solar cell panel is changed.

According to an embodiment of the present invention, the solar cell module may be inserted into the first fixing groove 112, and the first fixing groove 112 guides the solar cell module 10 to be accurately disposed on the first mold 100.

According to an embodiment of the present invention, the depth to which the first fixing groove 112 is recessed may be less than a thickness of the solar cell module 10. Due to the above structure, when the solar cell module 10 is inserted into the first fixing groove 112, some of the outer surfaces of the solar cell module 10 may be brought into contact with the prepreg 20 to be integrally formed with the prepreg 20 in a manufactured solar cell panel.

According to an embodiment of the present invention, a release material layer 5 may be formed on an outer surface of the first mold 100 before the solar cell module 10 is disposed on the first mold 100. The release material layer 5 may be formed on the entire outer surfaces of the first mounting space 110 of the first mold 100 and the first fixing groove 112.

The release material layer 5 may be formed to prevent a resin contained in the prepreg 20, which is to be compressed and stacked in subsequent operations, from being eluted and attached to the first mold 100, and may be formed by attaching a release film or applying a release agent.

Therefore, in the disposing of the solar cell module (S100), the solar cell module 10 may be inserted into the first fixing groove 112 of the first mold 100 in which the release material layer 5 is formed on the outer surface thereof, and fixedly positioned in the first fixing groove 112.

Next, in the stacking of the prepreg (S200) according to an embodiment of the present invention, the prepreg 20 may be stacked to cover exposed portions of the solar cell module 10.

The prepreg 20 is formed of fibrous cloth in which a fiber is impregnated with a resin in advance, and a user may stack a prepreg in multiple layers on a desired position to a desired thickness.

Accordingly, the prepreg 20 may be stacked to the desired thickness to cover outer sides of the first mold 100 having the release material layer 5 and an exposed portion, e.g., portions of a top surface and an outer side, of the solar cell module 10.

In an embodiment of the present invention, the prepreg 20 may be stacked such that a first region S1 and a second region S2 thereof have different thicknesses t1 and t2.

The first region S1 is a region spaced a certain distance from an inner side of the first mounting space 110 and corresponding to the solar cell module 10, and the second region S2 is a region having a certain width and formed along the inner side of the first mounting space 110.

The prepreg 20 may have a first thickness t1 in the first region S1 and have a second thickness t2 in the second region S2, and the second thickness t2 may be greater than the first thickness t1.

Next, the performing of the sealing (S300) and the performing of the compressing and hardening (S400) may be performed to form a vacuum bag.

In the performing of the sealing (S300) according to an embodiment of the present invention, a stacked structure including the solar cell module 10 and the prepreg 20 and having a curved shape may be covered with a bagging film 6. The bagging film 6 may be attached to an outer side of the first mold 100 via a sealant 7 provided along an edge of the bagging film 6 to seal an inner space of the bagging film 6 from the outside.

In the performing of the compressing and hardening (S400) according to an embodiment of the present invention, a connector 8 communicating with the inside of the bagging film 6 is provided and connected to a vacuum pump (not shown) through a vacuum hose 9 to apply vacuum pressure to the inside of the bagging film 6, thereby causing the bagging film 6 to be in a vacuum state.

After causing the bagging film 6 to be in the vacuum state, the first mold 100 may be placed in a chamber of an autoclave and heat and pressure may be applied thereto to compress a first solar cell panel 150 including the prepreg 20. A temperature and pressure in the chamber of the autoclave are adjustable if necessary for compressing the prepreg 20.

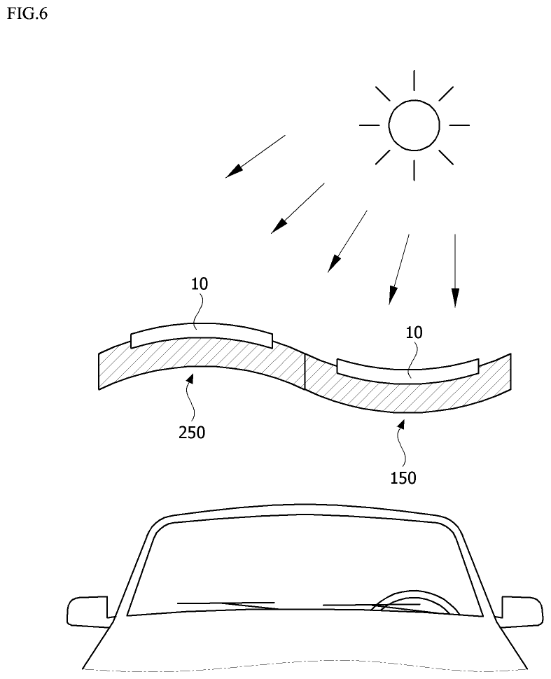

After the performing of the compressing and hardening (S400), when a first solar cell panel 150 including the prepreg 20 is taken out of the first mold 100, the first solar cell panel 150 having a concave portion in which the light transmission layer 13 is provided and a concave portion in which the prepreg 20 is provided may be manufactured (see FIG. 6).

A solar cell panel manufactured as described above may be provided as a highly rigid and lightweight component of a body of a vehicle and may generate solar light when applied to a loop of the body of the vehicle.

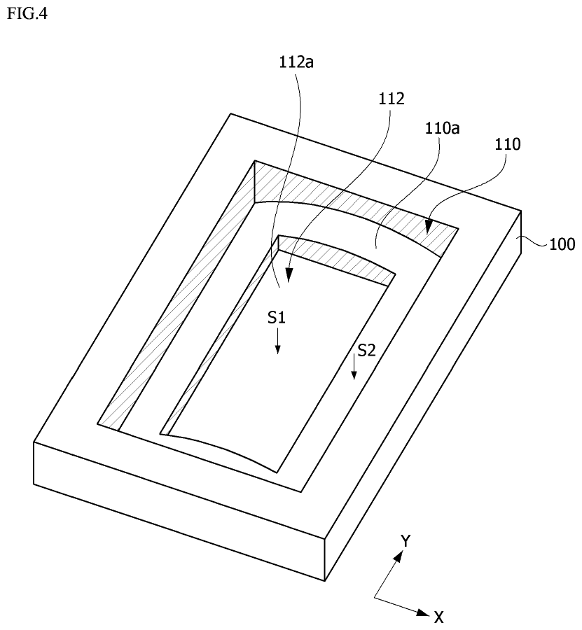

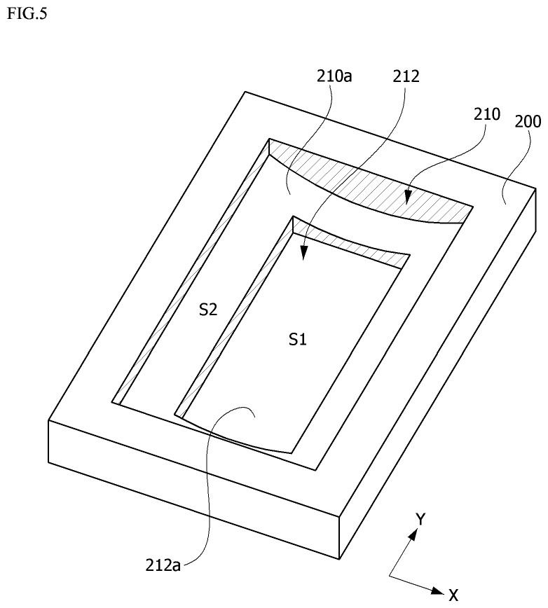

FIG. 4 is a cross-sectional view illustrating a process of a manufacturing method of a solar cell panel according to a second embodiment of the present invention. FIG. 5 is a schematic diagram of a second mold for manufacturing a solar cell panel according to the second embodiment of the present invention.

The solar cell panel according to the second embodiment of the present invention may be manufactured using a second mold 200 different from the first mold 100 used to manufacture the solar cell panel according to the first embodiment.

Referring to FIGS. 4 and 5, the second mold 200 may include a second mounting space 210 for forming a solar cell panel having a curved surface, and the second mounting space 210 may be formed in a quadrilateral shape when viewed from a plane and include a second mounting surface 210a having a concave shape with a constant curvature on an xy plane.

A second fixing groove 212 into which a solar cell module 10 is insertable may be formed in the second mounting surface 210a, and may be recessed to a certain depth while forming a step with the second mounting surface 210a of the second mounting space 210.

The second fixing groove 212 may be formed with a second fixing bottom surface 212a that is concave on the xy plane, and the second fixing bottom surface 212a may have a concave shape having the same curvature as the second mounting surface 210a of the second mounting space 210 but the second fixing bottom surface 212a and the second mounting surface 210a may have different curvatures according to a degree to which the solar cell module 10 is curved. According to an embodiment of the present invention, the solar cell module 10 may be inserted into the second fixing groove 212, and the second fixing groove 212 may increase the accuracy of arrangement of the solar cell module 10 with respect to the second mold 200.

According to an embodiment of the present invention, the depth to which the second fixing groove 212 is recessed may be less than the thickness of the solar cell module 10.

An order in which a solar cell panel according to the second embodiment of the present invention is manufactured using the second mold 200 is the same as the order in which the solar cell panel according to the first embodiment is manufactured and thus a description thereof will be omitted here.

A second solar cell panel 250 manufactured by the manufacturing method according to the second embodiment of the present invention may have a convex portion in which a light transmission layer 13 is provided and a concave portion in which a prepreg 20 is provided.

FIG. 6 is a schematic cross-sectional view illustrating a state in which a first solar cell panel according to the first embodiment and a second solar cell panel according to the second embodiment of the present invention are connected to each other on the top of a vehicle.

A first solar cell panel 150 in which a solar cell module 10 is formed in a concave shape may be disposed on a concave portion of the top of a vehicle and a second solar cell panel 250 in which a solar cell module 10 is formed in a convex shape may be disposed on an upwardly convex portion of the top of the vehicle.

In addition, a degree to which a solar cell panel, which is a curved stacked structure, is bent may be adjusted by forming a mounting space of a mold and a fixing groove in different forms.

Therefore, solar cell panels having different shapes may be combined together and disposed according to a shape of the top of a vehicle.

While the present invention has been described above with reference to the embodiments illustrated in the drawings, these embodiments are merely examples and it will be understood by those of ordinary skill in the art that various modifications and other equivalent embodiments may be made. Therefore, the technical scope of the present invention should be defined by the technical idea of the appended claims.

1. A method of manufacturing a solar cell panel using an autoclave, the method comprising:
(a) disposing at least one solar cell module on a mold having a release material layer;
(b) stacking a prepreg to a certain thickness on the mold to cover the solar cell module;
(c) covering a stacked structure of the solar cell module and the prepreg with a bagging film and sealing an inner space of the bagging film from the outside; and
(d) making the inner space of the bagging film into a vacuum state, placing the mold into a chamber of an autoclave, and applying heat and pressure to compress and harden the prepreg,
wherein, in operation (b), the mold is provided with a mounting space for forming the solar cell panel, and the prepreg is stacked in a state in which the solar cell module is inserted into a fixing groove formed in a mounting surface of the mounting space.

2. The method of claim 1, wherein, in the mold, the mounting surface has a certain curvature and is upwardly convex.

3. The method of claim 1, wherein, in the mold, the mounting surface has a certain curvature and is concave.

4. The method of claim 2, wherein, in operation (b), the fixing groove is recessed to a depth sufficient to outwardly expose a portion of the solar cell module, and the prepreg is stacked to cover the exposed portion.

5. The method of claim 4, wherein the prepreg comprises
a first region corresponding to the solar cell module, and a second region formed in a peripheral region of the first region along an inner side of the mounting space, and
in operation (b), the prepreg is stacked to be thicker in the second region than in the first region.

6. The method of claim 3, wherein, in operation (b), the fixing groove is recessed to a depth sufficient to outwardly expose a portion of the solar cell module, and the prepreg is stacked to cover the exposed portion.
